(19) United States
(12) Patent Application Publication
(10) Pub. No.: US 2009/0250809 A1
(43) Pub. Date: Oct. 8, 2009

(54) Semiconductor package having thermal stress canceller member

(75) Inventor: Yuichi Yoshida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/382,613

(22) Filed: Mar. 19, 2009

(30) Foreign Application Priority Data
Apr. 4, 2008 (JP) 2008-097295

(51) Int. Cl. H01L 23/34; H01L 23/00

(52) U.S. Cl. 257/723; 257/729; 257/E23.08; 257/E23.002

(57) ABSTRACT

A semiconductor package includes a package-substrate, a first cavity formed on a first main surface of the package substrate, a first semiconductor chip mounted on the bottom surface of the first cavity, a first resin layer filled into the first cavity, and a thermal stress canceller member mounted on the package substrate for cancelling the thermal stress caused by the difference in the thermal expansion rates between the package substrate and mounting section including a first semiconductor chip and a first resin layer. The thermal stress canceller member may include a second cavity, a second resin layer filled into the second cavity, and a semiconductor chip.

### BACKGROUND OF THE INVENTION

1. Field of the Invention

The present invention relates to a semiconductor package where a semiconductor chip is mounted on a package substrate.

2. Description of Related Art

Electronic equipment and hand-held devices of various types are constantly being made more compact and lighter in weight, so the semiconductor packages used in those devices and equipment must also be reduced in size, be made lighter, and to a thinner profile. Moreover, there is a growing trend to increase the number of external terminals for data input/output on semiconductor packages in order to keep pace with increasingly sophisticated and higher performance electronic equipment and other devices. These circumstances have led to the widespread use of surface-mounted semiconductor packages containing many external terminals on one surface of the semiconductor package. This type of surface-mounted semiconductor package should be positioned in as level a state as possible when being mounted on wiring boards. When there are curvatures such as warping in the semiconductor package, the gap between the pads on the wiring board and their corresponding external terminals becomes larger or similar effects occur, causing poor connections, and leading to potential connection defects.

FIG. 16 is a drawing showing an example of the semiconductor package. In this semiconductor package, a semiconductor chip 110 is mounted by way of an electrical connection on a package substrate 100 and the entire upper surface is covered by a sealant resin 120. External terminals 130 for connecting to a wiring board (not shown in drawing) are formed on the lower surface of the package substrate 100.

Since the physical values such as the thermal expansion coefficients of the package substrate 100 and sealant resin 120 in the semiconductor package shown in FIG. 16 are different, a difference in the thermal expansion (or thermal contraction) in each material occurs when a temperature load is applied. A state then occurs where one side of package substrate 100 elongates and the opposite side contracts, and causes the problem of warping on the semiconductor package as shown in FIG. 17. The direction of warping shown in FIG. 17 is one example and might also occur in the opposite direction.

Warping in semiconductor packages is caused mainly due to the many different materials making up the semiconductor package, and occurs due to the difference in thermal expansion and contraction in each material when a temperature load is applied to materials with different physical values in the semiconductor package.

Patent Document 1 however discloses a semiconductor package with the object of preventing curvature on the organic substrate caused by the sealant resin used to protect elements mounted on the organic substrate, and enhance device reliability. In this semiconductor package, resin is utilized to seal the semiconductor elements mounted on one side of the organic substrate. An identical resin layer is formed on the opposite side of the organic substrate. Forming this resin layer on both sides of the organic substrate, serves to prevent curvature on the organic substrate when a contracting force is applied to both sides of the organic substrate during hardening of the resin. Moreover the elements and organic substrate in this semiconductor package are connected by wires.
[Patent Document 1] Japanese Patent Application Laid Open Hei5(1993)-4489

### SUMMARY

However, the semiconductor package disclosed in Patent Document 1 was intended to prevent curvature on the substrate caused by a contracting force occurring during hardening of the resin. Therefore, when a temperature load was applied, a difference in thermal expansion (contraction) occurred between the upper and lower sections of the organic substrate (package substrate) leading to possible warping of the semiconductor package.

A semiconductor package of an exemplary aspect of the invention includes, a package substrate including a first cavity formed on a first main surface of the package substrate, a first semiconductor chip mounted on a bottom surface of the first cavity, a first resin layer filled into the first cavity, and a thermal stress canceller member mounted on the package substrate for cancelling out a thermal stress caused by a difference in thermal expansion rates between the package substrate and a mounting section including the first semiconductor chip and the first resin layer.

The thermal stress canceller member cancels out the thermal stress caused by the difference in the thermal expansion rates between a package substrate and a mounting section including the first semiconductor chip and a first resin layer. The exemplary aspect of the present invention can therefore suppress the warping caused by thermal stress in the semiconductor package. Moreover, warping caused by thermal stress can virtually be eliminated by adjusting the thermal stress canceller member.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a cross sectional view of the semiconductor package of a first exemplary embodiment;

FIG. 2 is a plan view of the semiconductor package shown in FIG. 1;

FIG. 3 is a cross sectional view of the semiconductor package of a second exemplary embodiment;

FIG. 4 is a cross sectional view of the semiconductor package of a third exemplary embodiment;

FIG. 5 is a cross sectional view of an example of a variation of the semiconductor package of the third exemplary embodiment;

FIG. 6 is a cross sectional view of the semiconductor package of a fourth exemplary embodiment;

FIG. 7 is a cross sectional view of an example of a variation of the semiconductor package of the fourth exemplary embodiment;

FIG. 8 is a cross sectional view of the semiconductor package of a fifth exemplary embodiment;

FIG. 9 is a cross sectional view of the semiconductor package of a sixth exemplary embodiment;

FIG. 10 is a cross sectional view of the semiconductor package of a seventh exemplary embodiment;

FIG. 11 is a cross sectional view showing an essential portion of an example of a variation of the semiconductor package of the seventh exemplary embodiment;

FIG. 12 is a cross sectional view showing an essential portion of an example of a variation of the semiconductor package of the seventh exemplary embodiment;

FIG. 13 is a cross sectional view of the semiconductor package of an eighth exemplary embodiment;

FIG. 14 is a cross sectional view of the semiconductor package of a ninth exemplary embodiment;

FIG. 15 is a cross sectional view of the semiconductor package of a tenth exemplary embodiment;

FIG. 16 is a drawing showing an example of a semiconductor package; and

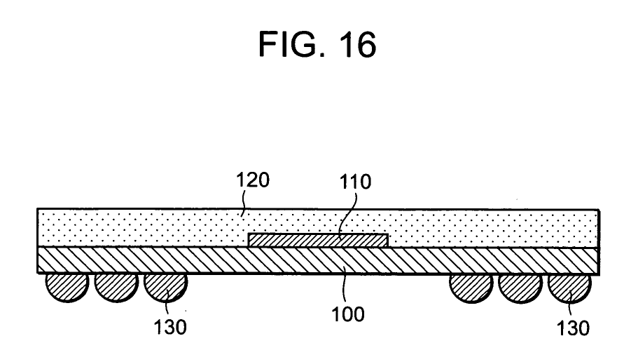

FIG. 17 is a drawing showing an example of warping occurring in the semiconductor package.

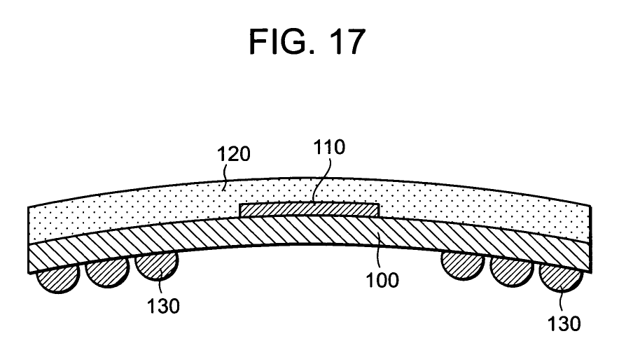

### DETAILED DESCRIPTION OF THE EXEMPLARY EMBODIMENTS

In the following exemplary embodiments, the semiconductor package includes a package substrate 10, a first cavity 12 formed on the package substrate 10, a first semiconductor chip 20, a first resin layer 30, and a thermal stress canceller member. The first cavity 12 is formed on the first main surface of the package substrate 10. The first semiconductor chip 20 is mounted on the bottom surface of the first cavity 12. The first resin layer 30 is filled into the first cavity 12. The thermal stress canceller member cancels out thermal stress caused by the difference in thermal expansion rates between the package substrate 10 and the mounting section 40 that includes the first semiconductor chip 20 and the first resin layer 30. The warping caused by thermal stress in the semiconductor package can therefore be suppressed. Moreover, warping caused by thermal stress can virtually be eliminated by adjusting items such as the configuration, the shape, and the material of the thermal cancel member.

An external terminal (for example, a bump) of first semiconductor chip 20 is formed on the bottom surface of the first cavity 12 and connects directly to a land positioned directly below this external terminal.

The thermal stress canceller member is made from a material and structure so that the thermal expansion coefficient of the first main surface side of package substrate 10, and the thermal expansion coefficient of the second main surface side on the side opposite the first main side are the same as each other. The first semiconductor chip 20 is moreover electrically connected to the package substrate 10. Each exemplary embodiment is specifically described next.

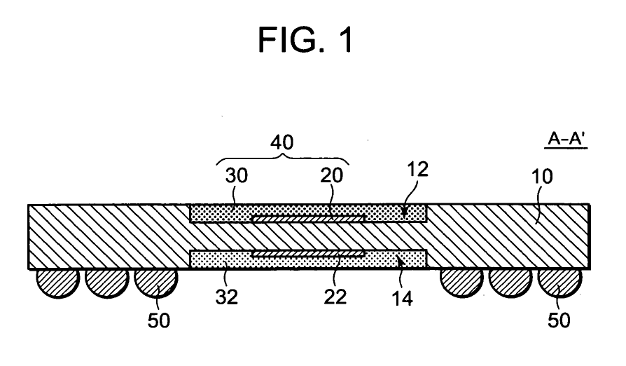

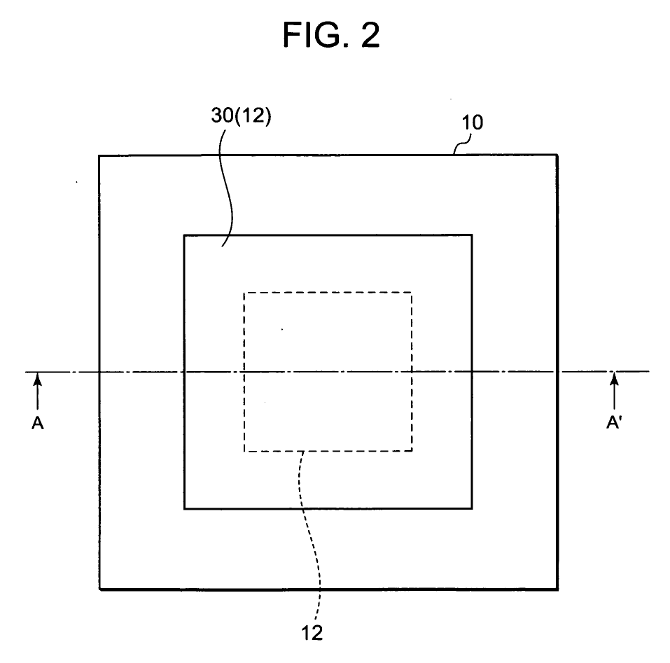

FIG. 1 is a cross sectional view of the semiconductor package of the first exemplary embodiment. FIG. 2 is a plan view of the semiconductor package shown in FIG. 1. FIG. 1 is a cross sectional view of lines A-A′ in FIG. 2. In this semiconductor package, the stress relaxer member contains a second cavity 14, a second semiconductor chip 22 mounted on the bottom surface of the second cavity 14, and a second resin layer 32 15 filled in the second cavity 14. The second cavity 14 is formed on the second main surface which is the surface opposite the first main surface of package substrate 10, and overlaps at least a portion of the first cavity 12 as seen from a direction perpendicular to the package substrate. An external terminal 50 connecting the semiconductor package to the wiring board (not shown in drawing) is moreover formed on the second main surface of the package substrate 10.

The substrate of the second semiconductor chip 22 is made from the same material as the substrate of the first semiconductor chip 20. These two substrates are the same thickness. The planar shape of the second semiconductor chip 22 is approximately the same as the planar shape of the first semiconductor chip 20. The planar shape and depth of the first cavity 12 in the example shown in this drawing are the same as the planar shape and depth of the second cavity 14. The second resin layer 32 is resin (for example, the same resin) having the same thermal expansion rate as the first resin layer 30. The first cavity 12 and the second cavity 14 are at the same position as seen from a direction perpendicular to the package substrate 10, and the first semiconductor chip 20 and the second semiconductor chip 22 are at the same position. Moreover the respective center positions of the first cavity 12, the second cavity 14, the first semiconductor chip 20, and the second semiconductor chip 22 are preferably at mutually identical positions.

In this semiconductor package, the upper and lower portions of the structure are symmetrical. Moreover the thermal expansion on the first main surface side and the second main surface side of the semiconductor package are equivalent to each other when the temperature has risen. Conversely, the thermal contraction on the first main side surface, and the second main side surface of the semiconductor package are also equivalent even when the temperature has dropped. There is therefore almost no warping on the semiconductor package, and connection defects between the external terminal 50 and the wiring board are prevented during mounting of the semiconductor package on the wiring board.

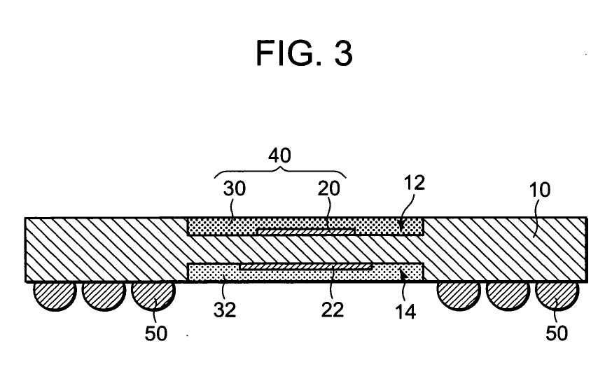

FIG. 3 is a cross sectional view of the semiconductor package of the second exemplary embodiment, and is equivalent to FIG. 1 of the first exemplary embodiment. Other than the point that the planar shape of the second semiconductor chip 22 is different from the planar shape of the first semiconductor chip 20, and the point that the first resin layer 30 and the second resin layer 32 are formed from different resins, this exemplary embodiment is the same as the first exemplary embodiment. The center of the second semiconductor chip 22 is at the same position as the center of the first semiconductor chip 20 as seen from a direction perpendicular to the package substrate 10. Moreover, the second semiconductor chip 22 in the example in this drawing is larger than the first semiconductor chip 20.

The planar shape of the second semiconductor chip 22 in this exemplary embodiment is different from the planar shape of the first semiconductor chip 20 and therefore the thermal stress originating in the first semiconductor chip 20 cannot be cancelled out by the thermal stress originating in the second semiconductor chip 22. However, the first resin layer 30 and the second resin layer 32 are formed from different resins and therefore the same effect as the first exemplary embodiment can be attained by setting the difference in thermal expansion coefficients of the resin to a suitable value.

In this exemplary embodiment, instead of making the resins of the first resin layer 30 and the second layer 32 different, the same effect can be obtained by changing the depth of the first cavity 12 and the second cavity 14. Moreover, besides using different resins for the first resin layer 30 and the second resin layer 32, the depth of the first cavity 12 and the second cavity 14 can be changed as well.

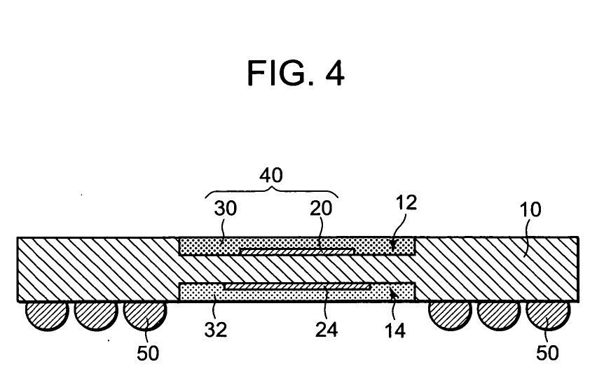

FIG. 4 is a cross sectional view of the semiconductor package of the third exemplary embodiment, and is equivalent to FIG. 3 of the second exemplary embodiment. Other than the point that a dummy chip is utilized as the substrate 24 rather than the second semiconductor chip 22, the present exemplary embodiment is the same as the second exemplary embodiment. The substrate 24 is formed for example from the same material as the second semiconductor chip 22, and the thickness is the same thickness as the substrate of the second semiconductor chip 22 or the second semiconductor chip 22.

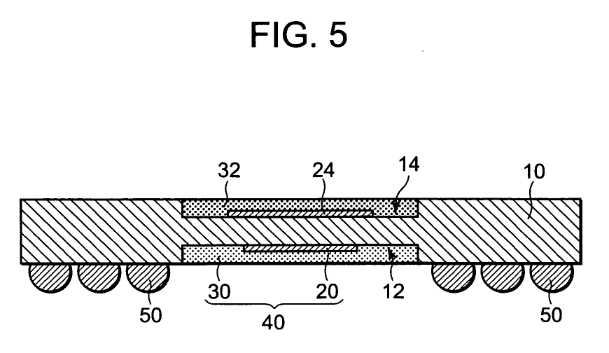

This exemplary embodiment also achieves the same effects as the second exemplary embodiment. In the modification of this exemplary embodiment shown in FIG. 5, the external terminal 50 may be formed on the first main surface rather than the second main surface. Moreover, the thermal stress may be adjusted using a metal substrate or a ceramic substrate instead of the substrate 24. The substrate 24 may also be utilized in the first exemplary embodiment instead of the second semiconductor chip 22. In this case, the planar shapes of the first semiconductor chip 20 and the substrate 24 are the same. Moreover, the first semiconductor chip 20 thickness or the first semiconductor chip 20 substrate thickness and the substrate 24 thickness are equivalent.

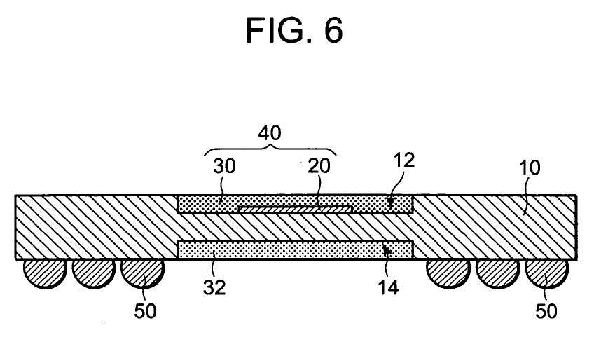

FIG. 6 is a cross sectional view of the semiconductor package of the fourth exemplary embodiment, and is equivalent to FIG. 1 of the first exemplary embodiment. Other than the point that this exemplary embodiment does not include a second semiconductor chip, as well as the point that the resins forming first resin layer 30 and the second resin layer 32 are different, the present exemplary embodiment is identical to the first exemplary embodiment.

In this exemplary embodiment, the first resin layer 30 and the second resin layer 32 are formed from different resins so the same effect as in the first exemplary embodiment can be obtained by setting the difference in thermal expansion coefficients to a suitable value even without also utilizing the second semiconductor chip 22.

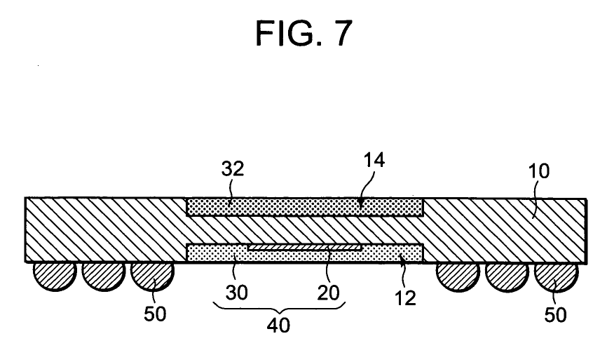

The present exemplary embodiment can cancel out the difference in thermal stress originating in the first semiconductor chip 20 and the thermal stress originating in the second semiconductor chip 22 by changing the depth of the first cavity 12 and the second cavity 14 instead of using different resins in the first resin layer 30 and the second resin layer 32. Moreover, different resins can be used in the first resin layer 30 and the second resin layer 32, and the depths of the first cavity 12 and the second cavity 14 also changed;. The external terminal 50 may be formed on the first main surface rather than the second main surface shown in the modification in FIG. 7.

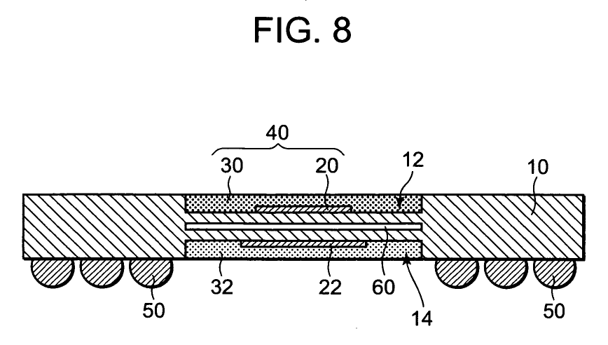

FIG. 8 is a cross sectional view of the semiconductor package of the fifth exemplary embodiment, and is equivalent to FIG. 3 of the second exemplary embodiment. Other than the point that the package substrate 10 includes a high-rigidity member 60, the present exemplary embodiment is the same as the second exemplary embodiment. The high-rigidity member 60 is a plate-shaped member formed from a high-rigidity material with higher rigidity than the body of the package substrate 10, and for example is a metallic plate or ceramic plate. The high-rigidity member 60 is positioned across the entire surface below the first cavity 12 as seen in the cross section of FIG. 8. More specifically, the high-rigidity member 60 is positioned between (i.e., an intermediate position) the bottom surface of the first cavity 12 and the bottom surface of the second cavity 14.

This exemplary embodiment also renders the same effects as the second exemplary embodiment. Moreover, the high-rigidity member 60 is positioned between the bottom of the second cavity 14 and the bottom of the first cavity 12 so that even if thermal stress occurs, the warping occurring within the semiconductor package will be small. Connection defects occurring between the external terminal 50 and the wiring board during mounting of the semiconductor package on the wiring board can therefore be prevented to an even greater extent.

The high-rigidity member 60 shown in this exemplary embodiment may also be mounted in the first, third and fourth exemplary embodiments.

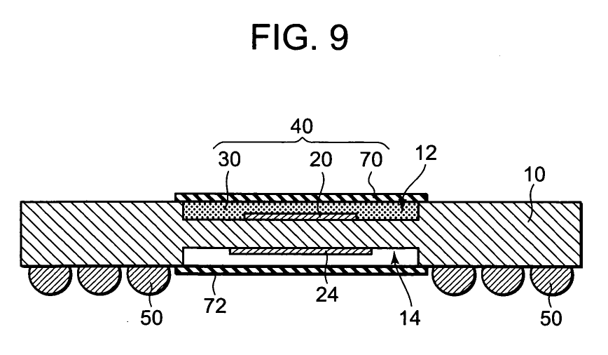

FIG. 9 is a cross sectional view of the semiconductor package of the sixth exemplary embodiment, and is equivalent to FIG. 4 of the third exemplary embodiment. Other than the point that the exemplary embodiment includes the covering members 70, 72 as a section of the stress relaxer member, and that there is no second resin layer 32, the present exemplary embodiment is the same as the third exemplary embodiment.

The covering member 70 covers the upper surface of the first cavity 12. The first resin layer 30 is filled into the space sealed by the covering member 70 and the first cavity 12.

The covering member 72 seals the second cavity 14. An inactive gas such as nitrogen is preferably filled into the space sealed by the covering member 72 and the second cavity 14.

The present exemplary embodiment can yield the same effect as the third exemplary embodiment by adjusting the respective planar shape, thickness, and material of the covering member 70, the substrate 24, and the covering member 72.

The second, fourth, and fifth exemplary embodiments may also include covering members 70, 72 in the same way as the present exemplary embodiment.

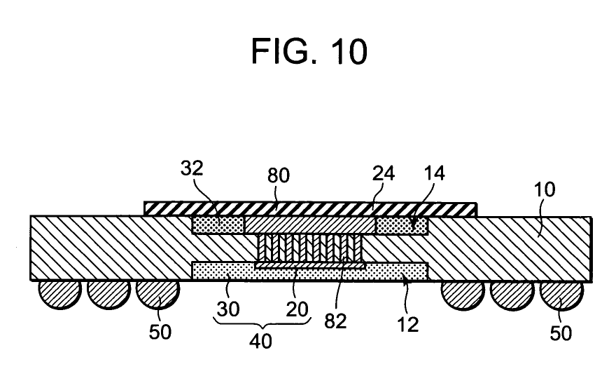

FIG. 10 is a cross sectional view of the semiconductor package of the seventh exemplary embodiment, and is equivalent to FIG. 5 of the third exemplary embodiment. This exemplary embodiment is the same as FIG. 5 of the third exemplary embodiment except for the following points.

A radiator plate 80 covers the second cavity 14. The radiator plate 80 is for example a copper plate or an aluminum plate. The thickness of the substrate 24 is approximately equivalent to the depth of the second cavity 14. Multiple thermal conductor members 82 are embedded in the package substrate 10 at a position between the first cavity 12 and the second cavity 14. The thermal conductor members 82 are formed from a material (i.e., metal-based material whose main constituent is copper) whose thermal conductivity is higher than the package substrate 10. The thermal conductor members 82 are embedded in through-holes penetrating from the bottom surface of the first cavity 12 to the bottom surface of the second cavity 14. The thermal conductor members 82 are respectively exposed from the bottom surface of the first cavity 12 and the bottom surface of the second cavity 14. One surface of the substrate 24 contacts radiator plate 80, and the other surface contacts the thermal conductor members 82.

This exemplary embodiment can also yield the same effect as the third exemplary embodiment by adjusting the respective planar shape, thickness, and material of the second resin layer 32, the substrate 24, and the radiator plate 80. The heat emitted from the first semiconductor chip 20 can also be radiated by way of the thermal conductor members 82 and the substrate 24, from the radiator plate 80.

In this exemplary embodiment, the second resin layer 32 need not be formed if the radiator plate 80 can seal the second cavity 14. Also, using a metal such as copper or aluminum as the material for the substrate 24 will improve the radiating performance for emitting heat from the first semiconductor chip 20.

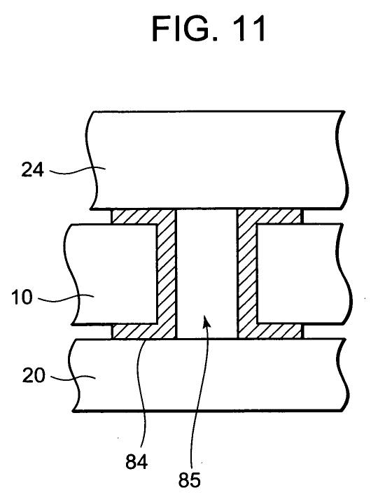

A thermal conductor member 84 may be formed as shown in FIG. 11 instead of the thermal conductor member 82. The thermal conductor member 84 is an electrically conductive film formed in an area positioned on the inner circumferential side surfaces of the through-hole 85 penetrating above and below through the package substrate 10 positioned between the first cavity 12 and the second cavity 14, and also positioned on the periphery of the through-hole 85 among the bottom surface of the first cavity 12 and the bottom surface of the second cavity 14. The thermal conductor member 84 respectively contacts the first semiconductor 20 and the substrate 24. The thermal conductor member 84 is for example a copper film and may for example be formed by chemical plating.

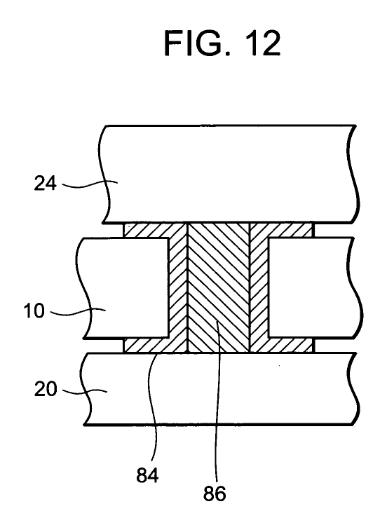

As shown in FIG. 12, a thermal conductor member 84 may be formed in the same way as in FIG. 11, and also a thermal conductor member 86 may be embedded in the space enclosing the thermal conductor member 84. The thermal conductor member 86 is for example made from copper and may for example be formed by embedding thermal conductive paste into the space enclosing the thermal conductor member 84. The thermal conductor member 86 contacts the first semiconductor chip 20 and the substrate 24, respectively.

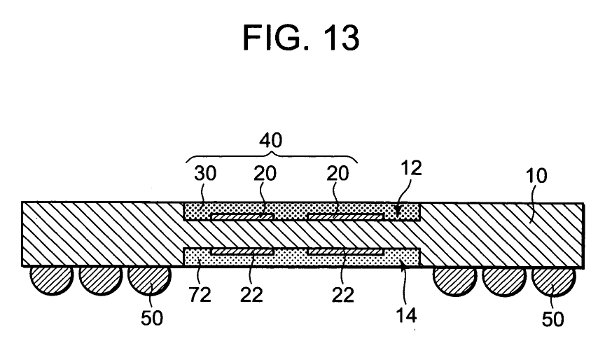

FIG. 13 is a cross sectional view of the semiconductor package of the eighth exemplary embodiment, and is equivalent to FIG. 1 of the first exemplary embodiment. Other than the point that multiple first semiconductor chips 20 are mounted on the bottom surface of the first cavity 12, and the point that multiple second semiconductor chips 22 are mounted on the bottom surface of the second cavity 14, the present exemplary embodiment has the same structure as the first exemplary embodiment:

The number of first semiconductor chips 20 is the same as the number of second semiconductor chips 22, and are at mutually identical positions as seen from a direction perpendicular to the package substrate 10. The first semiconductor chips 20 and the second semiconductor chips 22 mounted at identical positions are the same planar shape. The planar shapes of the multiple first semiconductor chips 20 may be different from each other.

This exemplary embodiment yields the same effect as the first exemplary embodiment. Moreover, there is no need to form multiple first cavities 12 and second cavities 14 so the production costs for the package substrate 10 are lower than the first exemplary embodiment.

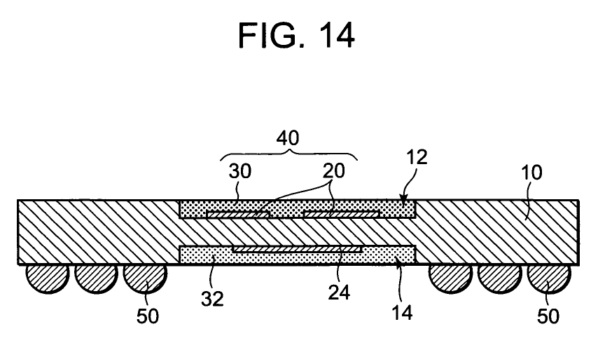

FIG. 14 is a cross sectional view of the semiconductor package of the ninth exemplary embodiment, and is equivalent to the eighth exemplary embodiment in FIG. 13. Other than the point that the substrate 24 is utilized instead of multiple second semiconductor chips 22, the present exemplary embodiment is equivalent to the eighth exemplary embodiment. The substrate 24 may be one piece or may be multiple pieces.

This exemplary embodiment can yield the same effect as the eighth exemplary embodiment by adjusting the position, shape, size and thickness of the substrate 24.

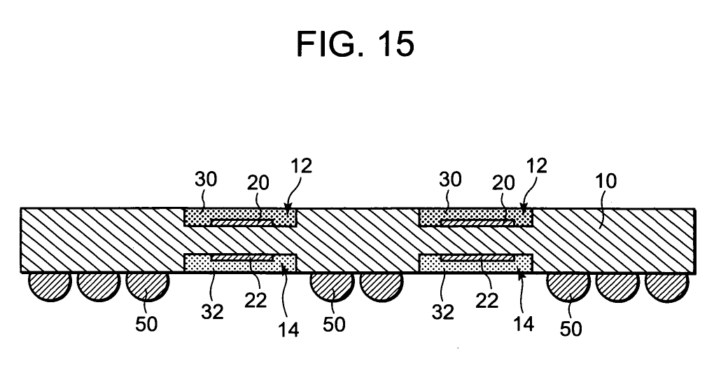

FIG. 15 is a cross sectional view of the semiconductor package of the tenth exemplary embodiment, and is equivalent to FIG. 1 of the first exemplary embodiment. Aside from the point that multiple first cavities 12 and multiple second cavities 14 are formed in identical quantities, the present exemplary embodiment is identical to the first exemplary embodiment.

The first semiconductor chips 20 are mounted in the bottom section of each of the first cavities 12, and a first resin layer 30 is filled into that first cavity 12. The second semiconductor chips 22 are mounted in the bottom section of each of the second cavities 14, and a second resin layer 32 is filled into the second cavities 14. The first cavity 12 and the second cavity 14 are at the same positions as seen from a direction perpendicular to the package substrate 10, and the first semiconductor chip 20 and the second semiconductor chip 22 are also at the same positions.

The present exemplary embodiment also yields the same effects as the first exemplary embodiment. At least one more second semiconductor chip 22 may be substituted for the substrate 24.

The exemplary embodiments of the invention were described while referring to the drawings. However the present invention is not limited to these examples and other structures may also be employed.

Further, it is noted that, Applicant's intent is to encompass equivalents of all claim elements, even if amended later during prosecution.

What is claimed is:

1. A semiconductor package, comprising:
a package substrate including a first cavity formed on a first main surface of the package substrate;
a first semiconductor chip mounted on a bottom surface of the first cavity;
a first resin layer filled into the first cavity; and
a thermal stress canceller member mounted on the package substrate for cancelling out a thermal stress caused by a difference in thermal expansion rates between the package substrate and a mounting section including the first semiconductor chip and the first resin layer.

2. The semiconductor package according to claim 1, wherein the thermal stress canceller member includes:
a second cavity that is formed on a second main surface which is opposite the first main surface of the package substrate, and overlaps with at least a portion of the first cavity; and
a second resin layer filled into the second cavity.

3. The semiconductor package according to claim 2, wherein the thermal stress canceller member includes a substrate mounted on a bottom surface of the second cavity, and overlaps with at least a portion of the first semiconductor chip.

4. The semiconductor package according to claim 3,
wherein a planar shape and a depth of the second cavity are the same as those of the first cavity,
wherein a planar shape of the first semiconductor chip is the same as that of the substrate,
wherein the second resin layer has a same thermal expansion rate as the first resin layer, and
wherein the first cavity and the second cavity are substantially at identical positions, and the first semiconductor chip and the substrate are substantially at identical positions, as seen from a direction perpendicular to the package substrate.

5. The semiconductor package according to claim 3, wherein the substrate comprises a second semiconductor chip.

6. The semiconductor package according to claim 3, further comprising:
a radiator plate that covers the second cavity, and contacts a surface of the substrate; and
a thermal conductor member that penetrates through the package substrate positioned between the bottom surface of the second cavity and the bottom surface of the first cavity, and is exposed on those respective two bottom surfaces,
wherein the thermal stress canceller member cancels out the thermal stress caused by a difference between a thermal expansion rate of the package substrate and the respective thermal expansion rates of the mounting section, the thermal conductor member, and the radiator plate.

7. The semiconductor package according to claim 1,
wherein the thermal stress canceller member includes:
a first covering member which covers an upper surface of the first cavity;
a second cavity that is formed on a second main surface which is opposite the first main surface of the package substrate, and overlaps the first cavity ; and
a second covering member that covers an upper surface of the second cavity.

8. The semiconductor package according to claim 7, wherein the thermal stress canceller member includes a substrate mounted on the bottom surface of the second cavity.

9. The semiconductor package according to claim 1, wherein the package substrate is positioned below the first cavity, and includes a high-rigidity member with higher rigidity than a body of the package substrate.

10. A semiconductor package, comprising:
a package substrate including a first cavity provided on a first surface of the package substrate and a second cavity provided on a second surface of the package substrate, the first surface being opposite to the second surface, the first cavity being arranged in symmetry, with respect to a layer provided between the first and second cavities, with the second cavity;
a first semiconductor chip provided in the first cavity;
a second semiconductor chip provided in the second cavity,
a first resin provided in the first cavity; and
a second resin provided in the second cavity.

11. The semiconductor package as claimed in claim 10,
wherein the first and second semiconductor chips have a same height, thickness and material, and the first and second resins have a same height, thickness and material.

12. The semiconductor package as claimed in claim 10,
wherein the first and second semiconductor chips have a different size, and the first and second resins have a different material to balance a thermal stress.

13. A semiconductor package, comprising:
a package substrate including a first cavity provided on a first surface of the package substrate and a second cavity provided on a second surface of the package substrate, the first surface being opposite to the second surface, the first cavity being arranged in symmetry, with respect to a layer provided between the first and second cavities, with the second cavity;
a first semiconductor chip provided in the first cavity;
a first resin provided in the first cavity; and
a second resin provided in the second cavity having a material different from a material of the first resin to compensate a thermal stress generated from the first semiconductor chip and the first resin.
